(19) United States
(12) Patent Application Publication
(10) Pub. No.: US 2026/0349310 A1
(43) Pub. Date: Nov. 5, 2026

(54) PACKAGE STRUCTURE

(71) Applicant: Taiwan Semiconductor Manufacturing Company, Ltd., Hsinchu (TW)

(72) Inventors: Chih-Hsin LU, Tainan City (TW); Chia-Chia LIN, Kaohsiung City (TW); Ching-Ho CHIN, Taoyuan City (TW); Chung-Hao TSAI, Changhua County (TW); Chuei-Tang WANG, Taichung City (TW); Chen-Hua YU, Hsinchu City (TW)

(21) Appl. No.: 19/742,411

(22) Filed: Jul. 15, 2026

Related U.S. Application Data
(62) Division of application No. 18/323,483, filed on May 25, 2023.

(51) Int. Cl. G02F 1/19; G02F 1/01; H10F 39/10; H10W 20/00; H10W 20/20; H10W 90/00; H10W 72/20; H10W 72/29; H10W 72/90; H10W 80/00

(52) U.S. Cl. CPC G02F 1/19; G02F 1/0147; H10F 39/10; H10W 20/023; H10W 20/20; H10W 90/00; G02F 2201/06; G02F 2202/36; H10W 72/252; H10W 72/29; H10W 72/90; H10W 72/941; H10W 72/952; H10W 72/953; H10W 80/333

(57) ABSTRACT

A package structure is provided. The package structure includes a substrate having a front-side surface and a back-side surface, and an electrical device formed over the front-side surface of a substrate. The package structure includes a dielectric layer formed below and in direct contact with the back-side surface of the substrate, and a first optical device formed in the dielectric layer. The package structure also includes a protective layer formed below or above the first optical device; and an electro-optic effect material layer formed in the protective layer.

### CROSS REFERENCE TO RELATED APPLICATIONS

This Application is a Divisional application of U.S. patent application Ser. No. 18/323,483, filed on May. 25, 2023, the entirety of which is incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

New packaging technologies, such as package on package (PoP), have begun to be developed, in which a top package with a device die is bonded to a bottom package, with another device die. By adopting the new packaging technologies, various packages with different or similar functions may be integrated together.

Although existing package structures and methods of fabricating package structure have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 shows perspective view of a semiconductor structure, in accordance with some embodiments of the disclosure.

FIGS. 2A to 2C illustrate cross-sectional representations of various stages of manufacturing the semiconductor structure shown along line A-A’ in FIG. 1, in accordance with some embodiments.

FIGS. 3A-3G show cross-sectional representations of various stages of forming a package structure, in accordance with some embodiments of the disclosure.

FIG. 4 shows a cross-sectional representation of a package structure, in accordance with some embodiments of the disclosure.

FIG. 5 shows a cross-sectional representation of a package structure, in accordance with some embodiments of the disclosure.

FIGS. 6A-6F show cross-sectional representations of various stages of forming a package structure, in accordance with some embodiments of the disclosure.

FIG. 7 shows a cross-sectional representation of a package structure, in accordance with some embodiments of the disclosure.

FIG. 8 shows a cross-sectional representation of a package structure 100f, in accordance with some embodiments of the disclosure.

FIGS. 9A-9D show cross-sectional representations of various stages of forming a package structure, in accordance with some embodiments of the disclosure.

FIG. 10 shows a cross-sectional representation of a package structure, in accordance with some embodiments of the disclosure.

FIG. 11 shows a cross-sectional representation of a package structure, in accordance with some embodiments of the disclosure.

FIGS. 12A-12C show cross-sectional representations of various stages of forming a package structure, in accordance with some embodiments of the disclosure.

FIG. 13 shows a cross-sectional representation of a package structure, in accordance with some embodiments of the disclosure.

FIG. 14 shows a cross-sectional representation of a package structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments for a package structure and method for forming the same are provided. The electrical device and the optical device are formed on opposite sidewall surfaces of the substrate. The substrate can be a wafer, and the electrical device (e.g. the semiconductor device) and the optical device (e.g. the first optical devices and the electro-optic effect material layer) are integrated into one wafer. Since the electrical device and the optical device are formed on single wafer or chip, rather on different chips, the passage of the electrical signals and the optical signals are reduced and the transmission speed of the electrical signals and the optical signals are improved.

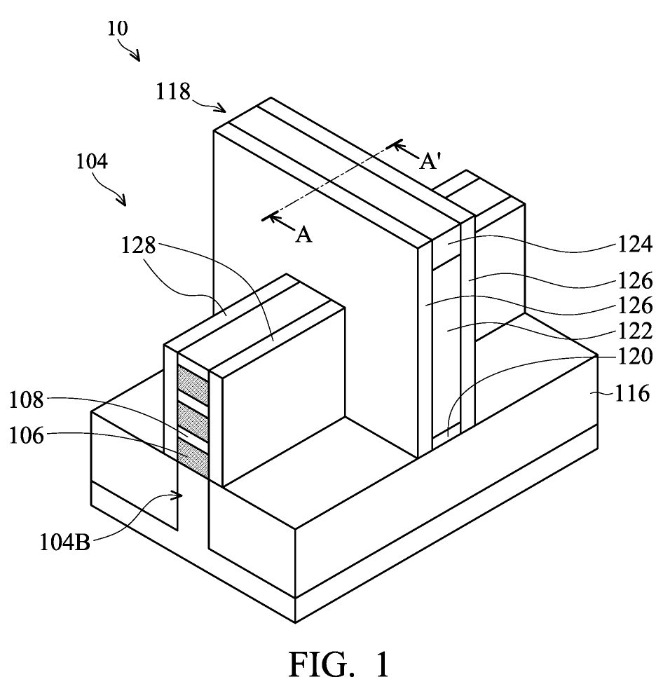

FIG. 1 shows perspective view of a semiconductor structure 10, in accordance with some embodiments of the disclosure. The semiconductor structure 10 is an electrical device.

Referring to FIG. 1, a substrate 102 is provided. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as a semiconductor material stack over the substrate 102, the semiconductor material stack is patterned to form a fin structure 104, in accordance with some embodiments. In some embodiments, the fin structure 104 includes a base fin structure 104B and the semiconductor material stack of the first semiconductor material layers 106 and the second semiconductor material layers 108.

After the fin structure 104 is formed, an isolation structure 116 is formed around the fin structure 104. After the isolation structure 116 is formed, a dummy gate structure 118 is formed across the fin structure 104 and extends over the isolation structure 116. The dummy gate structure 118 may be used to define the source/drain regions and the channel regions of the resulting semiconductor structure 10.

In some embodiments, the dummy gate structure 118 includes a dummy gate dielectric layer 120 and a dummy gate electrode layer 122. In some embodiments, the dummy gate dielectric layer 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 120 is formed using thermal oxidation, chemical vapor deposition (CVD), atomic vapor deposition (ALD), physical vapor deposition (PVD), another suitable method, or a combination thereof.

In some embodiments, the dummy gate electrode layer 122 includes conductive material. In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layer 122 is formed using chemical vapor deposition (CVD), physical vapor deposition (PVD), or a combination thereof.

In some embodiments, a hard mask layer 124 is formed over the dummy gate structure 118. In some embodiments, the hard mask layer 124 includes multiple layers, such as an oxide layer and a nitride layer. In some embodiments, the oxide layer is silicon oxide, and the nitride layer is silicon nitride.

After the dummy gate structure 118 is formed, gate spacers 126 are formed along and covering opposite sidewall surfaces of the dummy gate structure 118 and fin spacers 128 are formed along and covering opposite sidewall surfaces of the source/drain (S/D) regions of the fin structure 104, in accordance with some embodiments. The source/drain(S/D) structure or region(s) may refer to a source or a drain, individually or collectively dependent upon the context.

The gate spacers 126 may be configured to separate source/drain (S/D) structures from the dummy gate structure 118 and support the dummy gate structure 118, and the fin spacers 128 may be configured to constrain a lateral growth of subsequently formed source/drain (S/D) structure and support the fin structure 104.

In some embodiments, the gate spacers 126 and the fin spacers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacers 126 and the fin spacers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

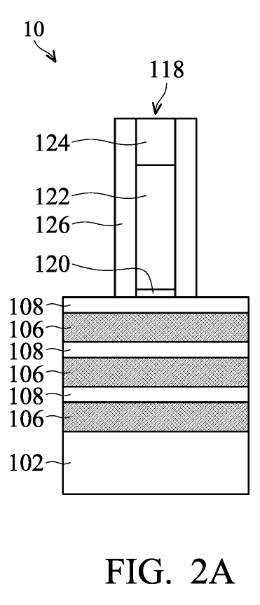

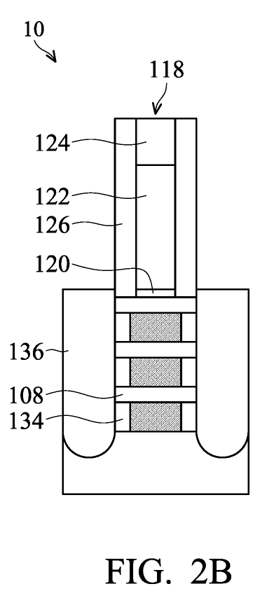

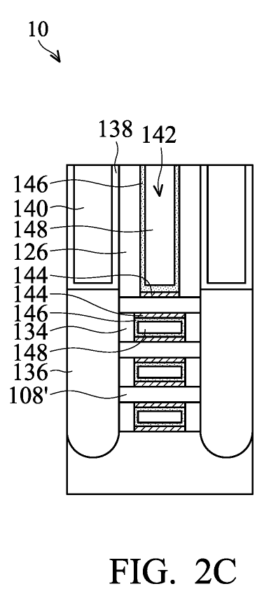

FIGS. 2A to 2C illustrate cross-sectional representations of various stages of manufacturing the semiconductor structure 10 shown along line A-A’ in FIG. 1, in accordance with some embodiments.

As shown in FIG. 2A, the dummy gate structure 118 is formed over the fin structure 104. The gate spacers 126 are formed on sidewall surfaces of the dummy gate structure 118. The dummy gate structure 118 includes the dummy gate dielectric layer 120 and the dummy gate electrode layer 122.

Next, as shown in FIG. 2B, the source/drain (S/D) regions of the fin structure 104 are recessed to form source/drain (S/D) recesses (not shown), in accordance with some embodiments. More specifically, the first semiconductor material layers 106 and the second semiconductor material layers 108 not covered by the dummy gate structures 118 and the gate spacers 126 are removed.

After the source/drain (S/D) recesses are formed, the first semiconductor material layers 106 exposed by the source/drain (S/D) recesses are laterally recessed to form notches (not shown), and the inner spacers 134 are formed in the notches between the second semiconductor material layers 108, in accordance with some embodiments.

The inner spacers 134 are configured to separate the source/drain (S/D) structures and the gate structures formed in subsequent manufacturing processes in accordance with some embodiments. In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 134 are formed by a deposition process, such as chemical vapor deposition (CVD) process, atomic layer deposition (ALD) process, another applicable process, or a combination thereof.

After the inner spacers 134 are formed, the source/drain (S/D) structures 136 are formed in the S/D recesses. In some embodiments, the S/D structures 136 are formed using an epitaxial growth process, such as molecular beam epitaxy (MBE), Metal-organic chemical vapor deposition (MOCVD), vapor-phase epitaxy (VPE), other applicable epitaxial growth process, or a combination thereof. In some embodiments, the S/D structures 136 are made of any applicable material, such as Ge, Si, GaAs, AlGaAs, SiGe, GaAsP, SiP, SiC, SiCP, or a combination thereof.

In some embodiments, the S/D structures 136 are in-situ doped during the epitaxial growth process. For example, the S/D structures 136 may be the epitaxially grown SiGe doped with boron (B). For example, the S/D structures 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the S/D structures 136 are doped in one or more implantation processes after the epitaxial growth process.

Afterwards, as shown in FIG. 2C, after the S/D structures 136 are formed, a contact etch stop layer (CESL) 138 is conformally formed to cover the S/D structures 136 and an interlayer dielectric (ILD) layer 140 is formed over the contact etch stop layers 138, in accordance with some embodiments.

In some embodiments, the contact etch stop layer 138 includes a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

The dummy gate structure 118 is replaced by a gate structure 142, in accordance with some embodiments. More specifically, the dummy gate structure 118 and the first semiconductor material layers 106 are removed to form nanostructures 108’ with the second semiconductor material layers 108, in accordance with some embodiments. The S/D structure 136 is attached to the nanostructures 108’.

The gate structures 142 wrap around the nanostructures 108’ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layer 144 is oxide layer formed around the nanostructures 108’ and on the top of the base fin structure 104B. In some embodiments, the interfacial layer 144 is formed by performing a thermal process.

In some embodiments, the gate dielectric layers 146 are formed over the interfacial layer 144, so that the nanostructures 108’ are surrounded (e.g. wrapped) by the gate dielectric layer 146. In addition, the gate dielectric layer 146 also covers the sidewalls of the gate spacers 126 and the inner spacers 134 in accordance with some embodiments. In some embodiments, the gate dielectric layer 146 includes one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al2O₃) alloy, another suitable high-k dielectric material, or a combination thereof. In some embodiments, the gate dielectric layer 146 is formed using chemical vapor deposition (CVD), atomic layer deposition (ALD), another applicable method, or a combination thereof.

In some embodiments, the gate electrode layer 148 is formed on the gate dielectric layer 146. In some embodiments, the gate electrode layer 148 includes one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 148 is formed using chemical vapor deposition (CVD), atomic layer deposition (ALD), electroplating, another applicable method, or a combination thereof. Other conductive layers, such as work function metal layers, may also be formed in the gate structure 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

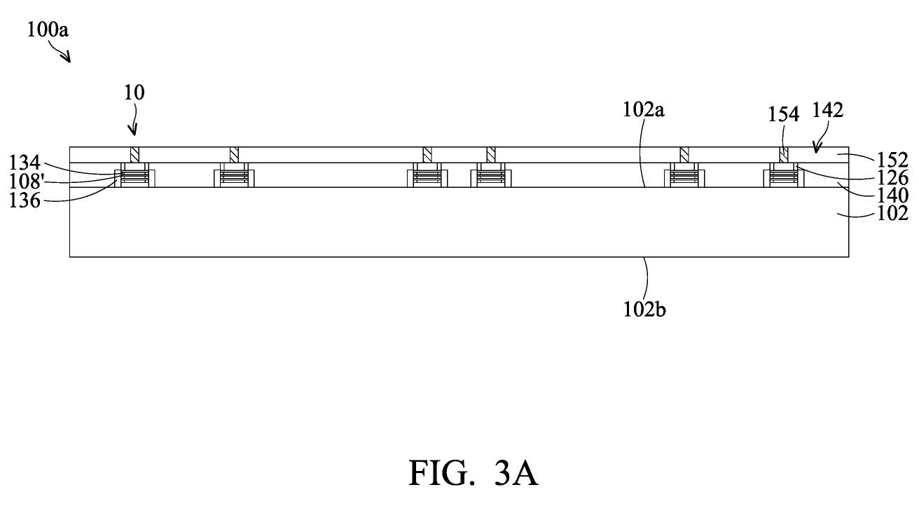

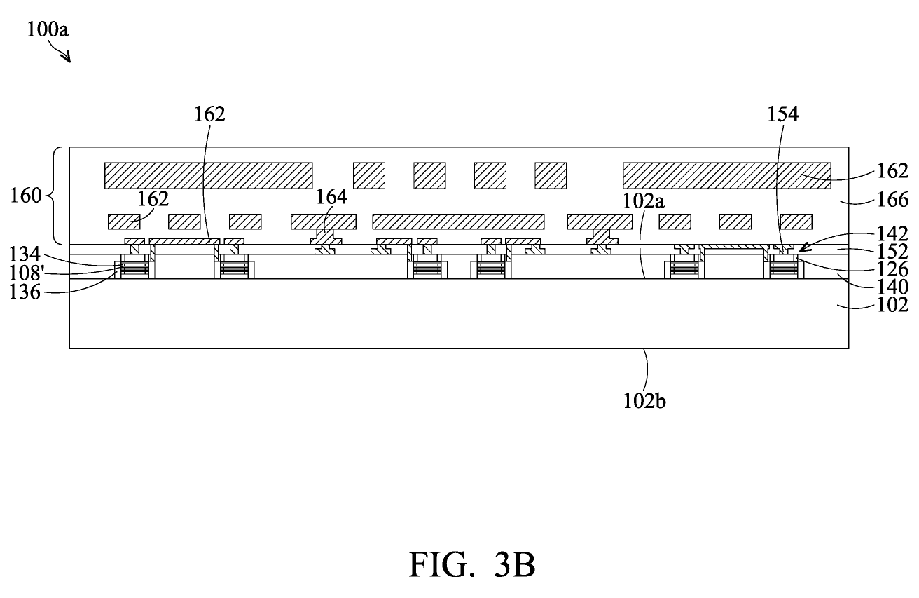

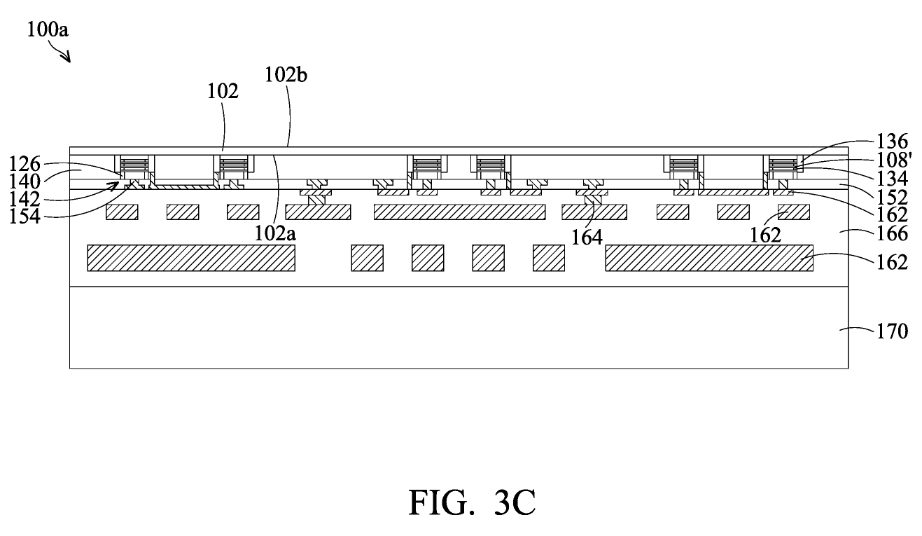

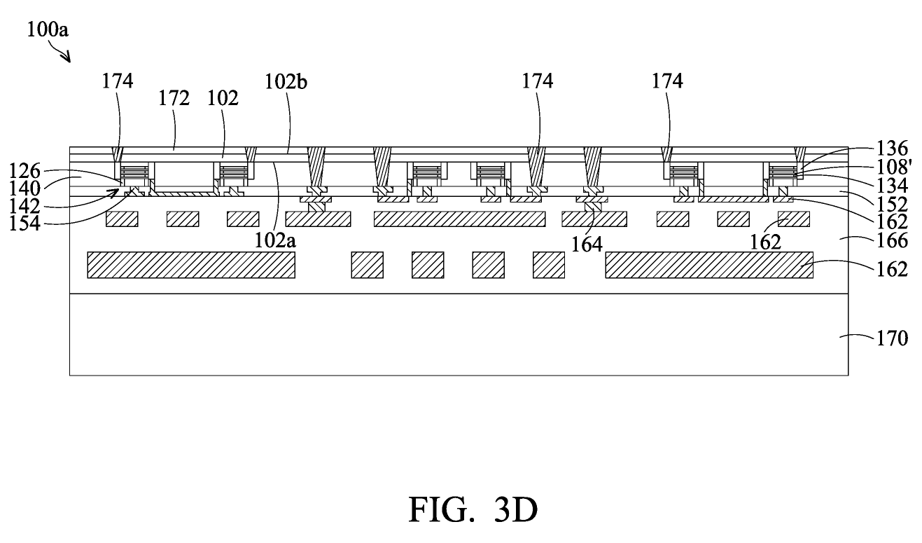

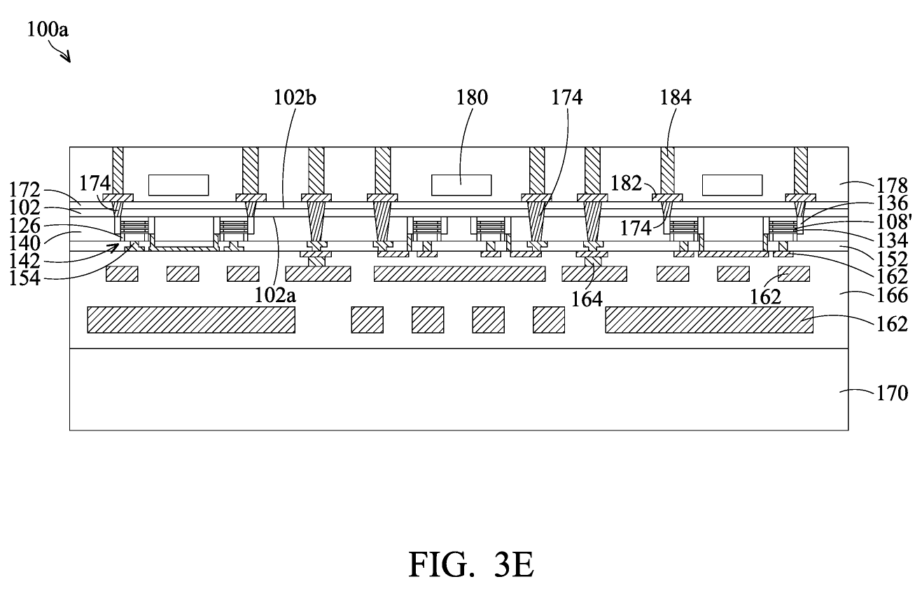

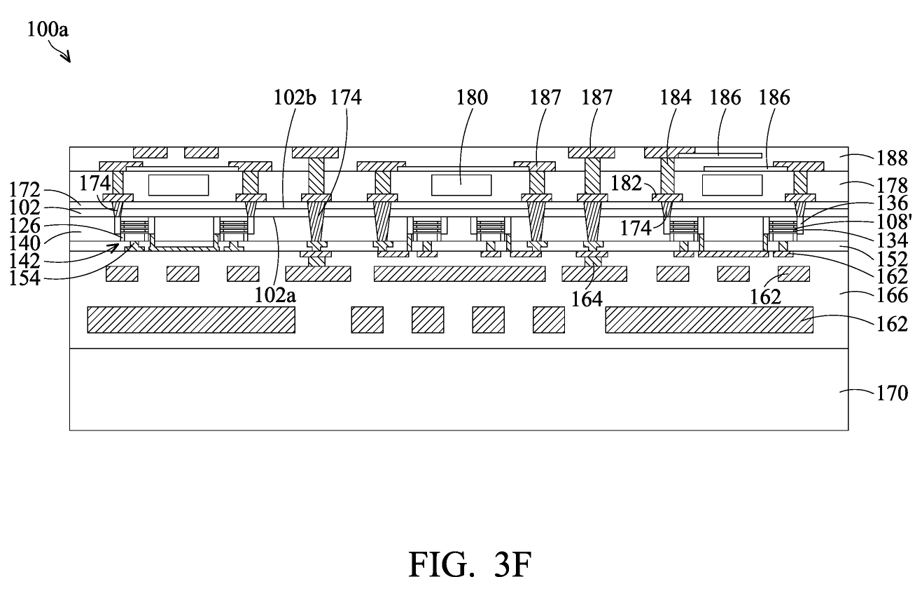

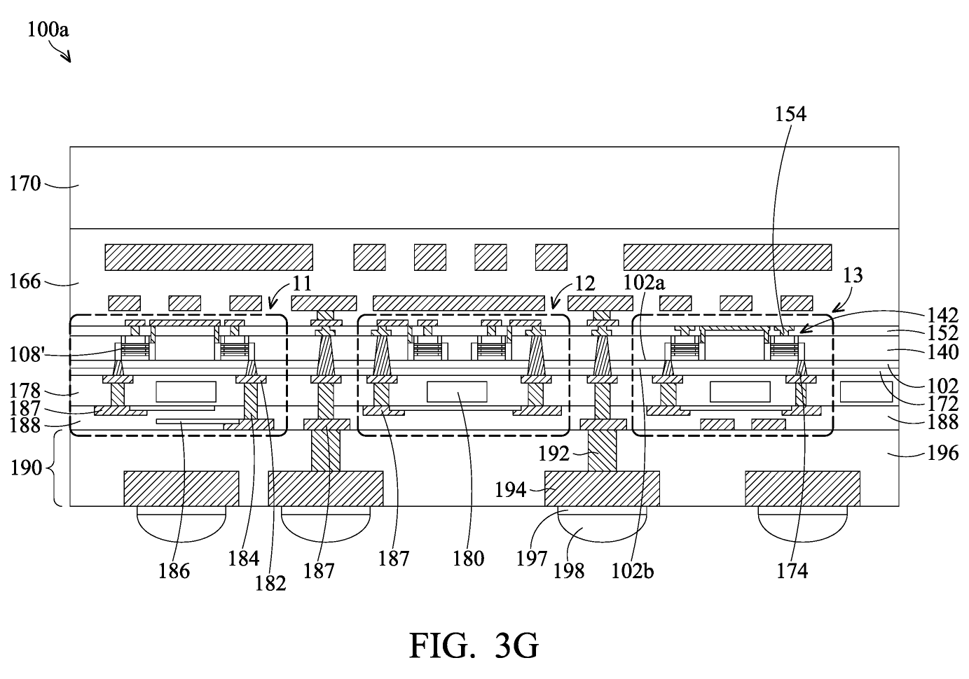

FIGS. 3A-3G show cross-sectional representations of various stages of forming a package structure 100a, in accordance with some embodiments of the disclosure.

As shown in FIG. 3A, the substrate 102 has a front-side surface 102a and a back-side surface 102b. The semiconductor structures 10 are formed over the front-side surface 102a of the substrate 102. Some elements of the semiconductor structures 10 are not shown in detail for clarity, the detail structure of the semiconductor structures 10 can refer to FIG. 2C. The number of the semiconductor structures 10 can be adjusted according to actual application.

A dielectric layer 152 is formed over the ILD layer 140, and a contact structure 154 is formed in the dielectric layer 152. The contact structure 154 is formed over and in direct contact with the gate electrode layer 148 of the gate structure 142.

The dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes

The contact structure 154 includes a conductive material including aluminum (Al), copper (Cu), tungsten (W), titanium (Ti), tantalum (Ta), titanium nitride (TiN), cobalt (Co), tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the contact structure 154 may be formed using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Next, as shown in FIG. 3B, an interconnect structure 160 is formed over the dielectric layer 152, in accordance with some embodiments of the disclosure. The interconnect structure 160 is a front-side interconnect structure. The interconnect structure 160 is formed in a back-end-of-line (BEOL). The interconnect structure 160 may be used as a redistribution layer (RDL) structure for routing.

The interconnect structure 160 includes conductive layers 162 and contact plugs 164 and dielectric layers 166. The conductive layers 162 and contact plugs 164 are embedded in the dielectric layer 166. In some embodiments, the conductive layers 162 and the contact plugs 164 are made of conductive materials, such as copper (Cu), copper alloy, aluminum (Al), aluminum alloys, combinations thereof or another applicable material. In some embodiments, the conductive layers 162 and the contact plugs 164 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 3C, the structure as shown in FIG. 3B is flipped and attached to a carrier substrate 170, in accordance with some embodiments of the disclosure. In some embodiments, the dielectric layer 166 is attached to the carrier substrate 170 by an adhesive layer (not shown). The adhesive layer is used as a temporary adhesive layer. The adhesive layer may be glue or a tape. In some embodiments, the adhesive layer is photosensitive and is easily detached from the carrier substrate 170 by light irradiation. For example, shining ultra-violet (UV) light or laser light on the carrier substrate 170 is used to detach the adhesive layer. In some other embodiments, the adhesive layer is heat-sensitive and is easily detached from the carrier substrate 170 when it is exposed to heat.

The carrier substrate 170 is configured to provide temporary mechanical and structural support during subsequent processing steps. The carrier substrate 170 includes glass, silicon oxide, aluminum oxide, metal, a combination thereof, and/or the like.

Next, the substrate 102 is thinned using the carrier substrate 170 as support, in accordance with some embodiments of the disclosure. In some embodiments, the substrate 102 is thinned from the back-side surface 102b. In some embodiments, the remaining substrate 102 is in a range from about 5 nm to about 100 nm. In some other embodiments, the substrate 102 is completely removed.

Next, as shown in FIG. 3D, a dielectric layer 172 is formed over and in direct contact with the back-side surface 102b of the substrate 102, and then through-substrate via (TSV) structures 174 are formed through the dielectric layer 172 and the substrate 102, in accordance with some embodiments of the disclosure. The TSV structures 174 may be referred to as through-silicon vias. More specifically, the TSV structures 174 penetrate through the dielectric layer 172 and the substrate 102. In some embodiments, some of the TSV structures 174 are connected to and in direct contact with the S/D structure 136. In some embodiments, some of the TSV structures 174 are in direct contact with the conductive plug 164, and the some of the TSV structures 174 are connected to the conductive layers 162 by the conductive plug 164.

The TSV structures 174 are formed by forming a number of trenches (not shown) which extend from the back-side surface 102b of the substrate 102 to a top surface of the dielectric layer 172. Afterwards, a liner layer (not shown) and a barrier layer (not shown) are filled into each of the trenches, and the conductive materials are formed on the barrier layer and in each of the trenches. Next, once the trenches have been filled, the excess liner layer, barrier layer and the conductive materials are removed by a planarization process, such as chemical mechanical polishing (CMP) process.

In some embodiments, the liner layer includes silicon nitride, although any other applicable dielectric may be used as an alternative. In some embodiments, the barrier layer includes tantalum nitride, although other materials, such as tantalum, titanium, titanium nitride, or the like, may also be used. In some embodiments, the conductive materials of the TSV structures 174 includes aluminum (Al), copper (Cu), tungsten (W), titanium (Ti), tantalum (Ta), or another applicable material. The liner layer, the barrier layers, and the conductive materials may be formed using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition processes. In some embodiments, each of the TSV structures 174 has a width in a range from about 15 nm to about 300 nm.

Afterwards, as shown in FIG. 3E, a dielectric layer 178 is formed over and in direct contact with the dielectric layer 172, and the first optical devices 180, the conductive layers 182 and the conductive plugs 184 are formed in the dielectric layer 178, in accordance with some embodiments of the disclosure. The first optical devices 180 are configured to transport the optical signal. The first optical devices 180 provide an optical medium for the light transmitting. The optical signal can be trapped and guided by the first optical devices 180. The first optical devices 180 can be controlled by the semiconductor device 10.

In some embodiments, the dielectric layer 178 includes low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

The first optical devices 180 may be optical waveguides (e.g., ridge waveguides, rib waveguides, buried channel waveguides, diffused waveguides, etc.), couplers (e.g., grating couplers, edge couplers, etc.), or the like. In some embodiments, the first optical devices 180 are a waveguide made of silicon nitride (SiN). In some embodiments, the material for the first optical devices 180 may be a translucent material.

In some embodiments, the first optical devices 180 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes. The first optical devices 180 may be formed by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

In some embodiments, the conductive layers 182 and the contact plugs 184 are made of conductive materials, such as copper (Cu), copper alloy, aluminum (Al), aluminum alloys, combinations thereof or another applicable material. In some embodiments, the conductive layers 182 and the contact plugs 184 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 3F, a electro-optic effect material layer 186, a conductive layer 187 and a protective layer 188 are formed over the dielectric layer 178, in accordance with some embodiments of the disclosure. The electro-optic effect material layer 186 and the conductive layer 187 are embedded in the protective layer 188. The electro-optic effect material layer 186 is in direct contact with the conductive layer 187 for transfer optical signal. The protective layer 188 is used to protect the electro-optic effect material layer 186. The electro-optic effect material layer 186 is electrically connected to the S/D structure 136 of the semiconductor structure 10 by the conductive plugs 184, the conductive layers 182 and the TSV structures 174.

Note that the first optical devices 180 and the electro-optic effect material layer 186 are formed over the back-side surface 102b of the substrate 102 for transfer the optical signal, and the electro-optic effect material layer 186 is electrically connected to the S/D structure 136 of the semiconductor structure 10 by the conductive layer 187, the conductive plugs 182, the conductive layers 184, and the TSV structures 174 for transfer the electrical signal of the semiconductor structure 10.

In some embodiments, the electro-optic effect material layer 186 includes graphene. In some embodiments, the electro-optic effect material layer 186 is a 2D material. The electro-optic effect material layer 186 may be one layer or multiple layers according to actual application. In some embodiments, the electro-optic effect material layer 186 is a monolayer and is attached to or bonding to the dielectric layer 178. In some embodiments, the electro-optic effect material layer 186 is made of graphene, and single layer graphene has a thickness in about 0.35 nm.

In some embodiments, the conductive layer 187 includes conductive materials, such as copper (Cu), copper alloy, aluminum (Al), aluminum alloys, combinations thereof or another applicable material. In some embodiments, the protective layer 188 includes aluminum oxide (Al₂O₃), silicon oxide (SiO₂), hafnium oxide (HfO₂) or a combination thereof. In some embodiments, the conductive layers 187 and the protective layer 188 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 3G, an interconnect structure 190 is formed over the protective layer 188, in accordance with some embodiments of the disclosure. Next, the structure of the FIG. 3G is flipped for clarity. The interconnect structure 190 is a back-side interconnect structure. The interconnect structure 160 may be used as a redistribution (RDL) structure for routing. The front-side interconnect structure 160 is formed over the semiconductor device 10, and the back-side interconnect structure 190 is formed below the protective layer 188.

The interconnect structure 190 includes the contact plugs 192, the conductive layers 194, the dielectric layers 196 and the UBM layers 197 and the conductive connectors 198. The contact plugs 192 and the conductive layers 194 are embedded in the dielectric layer 196. In some embodiments, the contact plugs 192 and the conductive layers 194 include conductive materials, such as copper (Cu), copper alloy, aluminum (Al), aluminum alloys, combinations thereof or another applicable material. In some embodiments, the contact plugs 192 and the conductive layers 194 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

In some embodiments, the UBM layers 197 include titanium (Ti), titanium nitride (TiN), tantalum (Ta), tantalum nitride (TaN), tungsten (W), titanium tungsten (TiW), nickel (Ni), gold (Au), chrome (Cr), copper (Cu), copper alloy, another applicable material, or a combination thereof. In some embodiments, the conductive connectors 198 include copper (Cu), a copper alloy, or another applicable material. In some embodiments, the UBM layers 197 and conductive connectors 198 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

The thickness of the conductive layer 194 of the interconnect structure 190 is greater than the thickness of the conductive layer 162 of the interconnect structure 160. The thick conductive layer 194 has low resistance to provide a quick passage of power and ground. In addition, the power delivery network (PDN) is improved.

As shown in FIG. 3G, the first region 11, the second region 12 and the third region 13 respectively have different functions. The first region 11 is a phase shifter region, and the refractive index of the electro-optic effect material layer 186 can be changed by supplying different voltage. In addition, the electro-optic effect material layer 186 can be controlled by the semiconductor device 10 through the TSV structure 174. The second region 12 is a heater region, and the refractive index of the electro-optic effect material layer 186 can be changed by heating process. The third region 13 is a photodetector region, and the electro-optic effect material layer 186 is a sensor of light or other electromagnetic radiation.

The semiconductor device 10 is formed on front-side surface 102a of the substrate 102, and the first optical devices 180 and the electro-optic effect material layer 186 embedded in the protective layer 188 are formed on back-side surface 102b of the substrate 102. The semiconductor device 10 can receive and process the electrical signal, and the first optical devices 180 and the electro-optic effect material layer 186 can receive and process the optical signals. The substrate 102 can be a wafer, and the electrical device (e.g. the semiconductor device 10) and the optical device (e.g. the first optical devices 180 and the electro-optic effect material layer 186) are integrated into one wafer. Note that bonding layer is absent between the electrical device (e.g. the semiconductor device 10) and the optical device (e.g. the first optical devices 180 and the electro-optic effect material layer 186). Since the electrical device and the optical device are formed on single wafer or chip, rather on different chips, the passage of the electrical signals and the optical signals are reduced. In other words, the routings of the optical signal or the electrical signal are reduced. Therefore, the transmission speed of the electrical signals and the optical signals are improved.

Furthermore, the back-side interconnect structure 190 and the first optical devices 180 are formed on back-side surface 102b of the substrate, and back-side area or routing area is shared by the back-side interconnect structure 190 and the first optical devices 180 to save routing area.

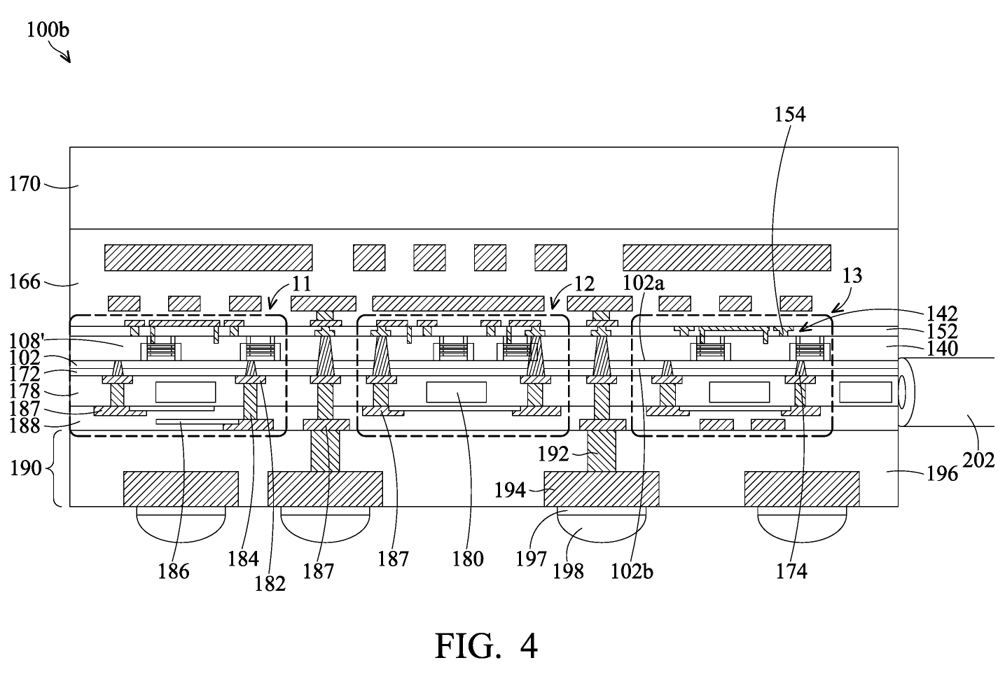

FIG. 4 shows a cross-sectional representation of a package structure 100b, in accordance with some embodiments of the disclosure. The package structure 100b is similar to, or the same as, the package structure 100a shown in FIG. 3G. Processes and materials used to form semiconductor device structure 100b may be similar to, or the same as, those used to form the semiconductor device structure 100a and a detailed description thereof is not repeated herein.

The difference between FIG. 4 and FIG. 3G is that additional optical fiber 202 is formed adjacent to the first optical devices 180. The optical fiber 202 is used as an input/output port to the optical signal of the first optical devices 180. By placing the optical fiber 202 adjacent to the first optical devices 180, the optical signals leaving the optical fiber 202 are directed through the first optical devices 180. The optical signal is coupled by the optical fiber 202.

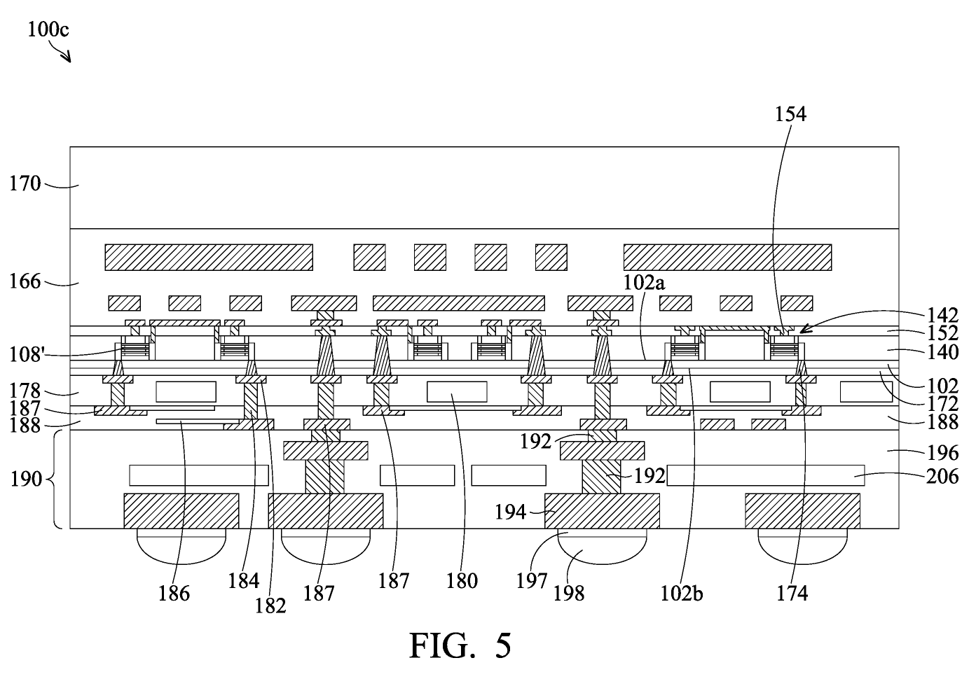

FIG. 5 shows a cross-sectional representation of a package structure 100c, in accordance with some embodiments of the disclosure. The package structure 100c is similar to, or the same as, the package structure 100a shown in FIG. 3G. Processes and materials used to form semiconductor device structure 100c may be similar to, or the same as, those used to form the semiconductor device structure 100a and a detailed description thereof is not repeated herein.

The difference between FIG. 5 and FIG. 3G is that the second optical devices 206 are formed in the dielectric layer 196 of the back-side interconnect structure 190. The second optical devices 206 are formed below the electro-optic effect material layer 186. The second optical devices 206 and the first optical devices 180 cooperate to transfer the optical signal more efficiency. In addition, by forming the second optical devices 206, the cross-talk can be further reduced.

The second optical devices 206 may be optical waveguides (e.g., ridge waveguides, rib waveguides, buried channel waveguides, diffused waveguides, etc.), couplers (e.g., grating couplers, edge couplers, etc.), or the like. In some embodiments, the second optical devices 206 are a waveguide made of silicon nitride (SiN). In some embodiments, the material for the second optical devices 206 may be a translucent material. In some embodiments, the second optical devices 206 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

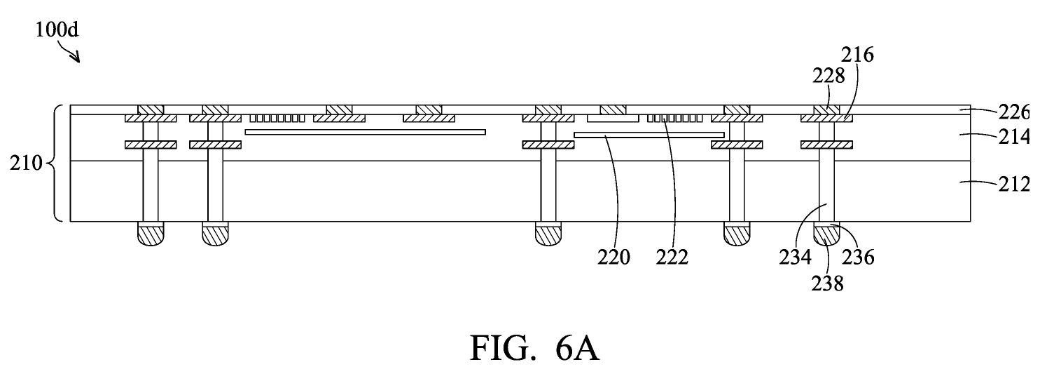

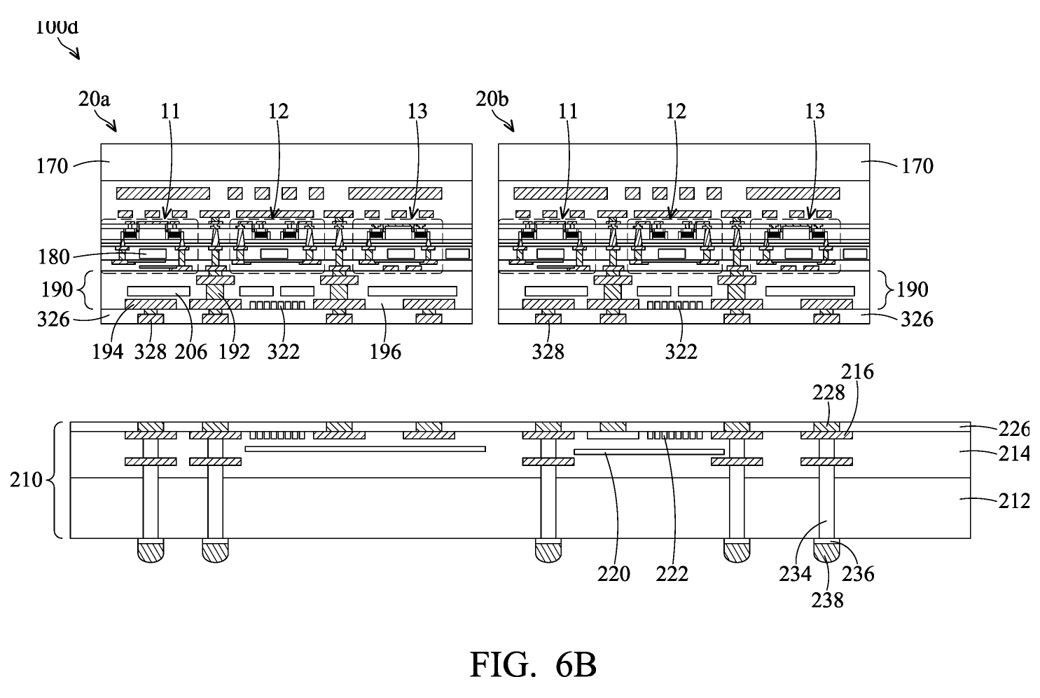

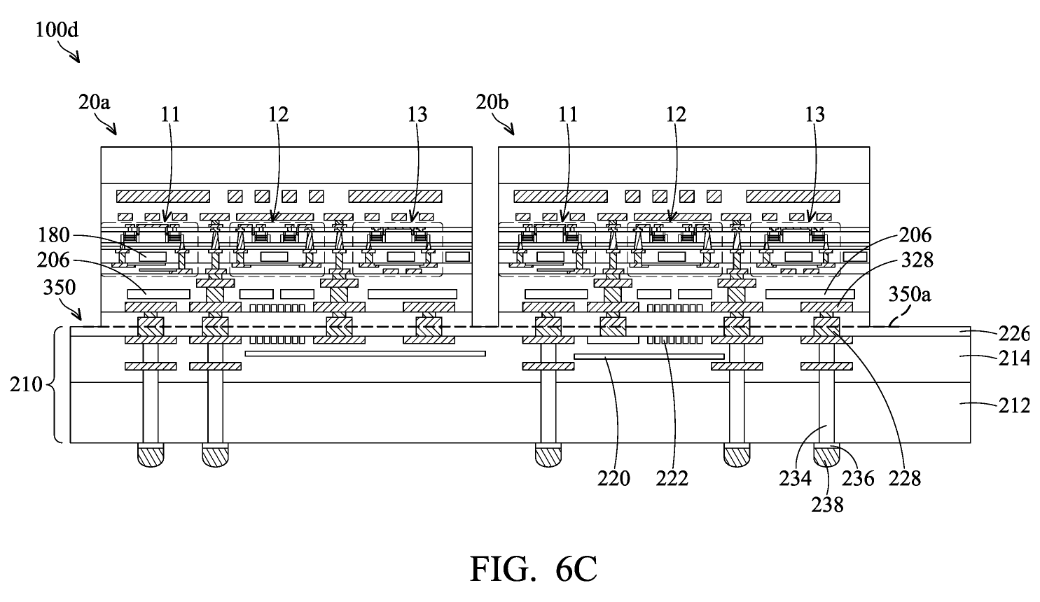

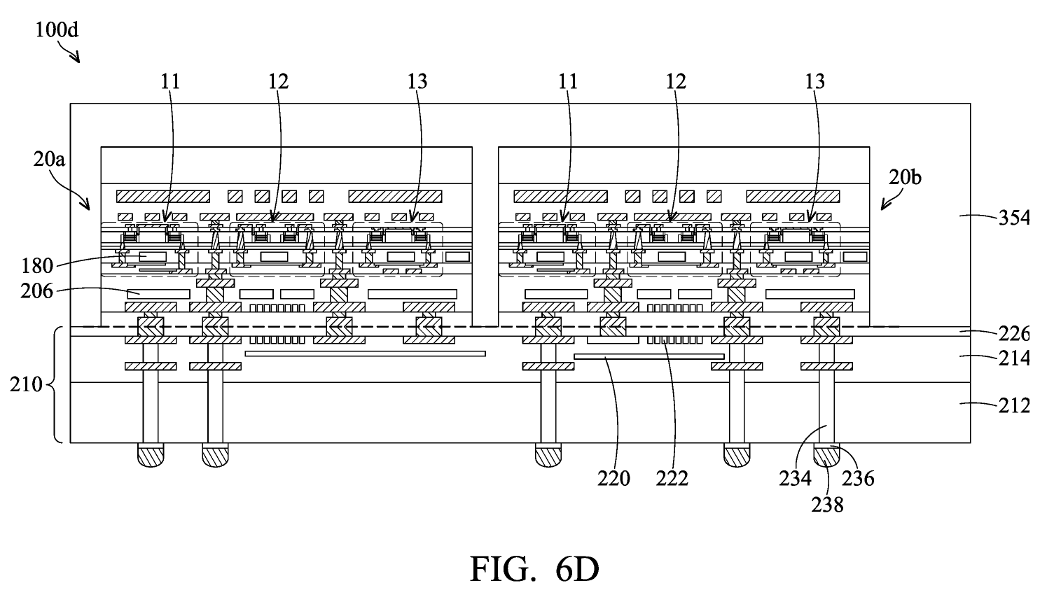

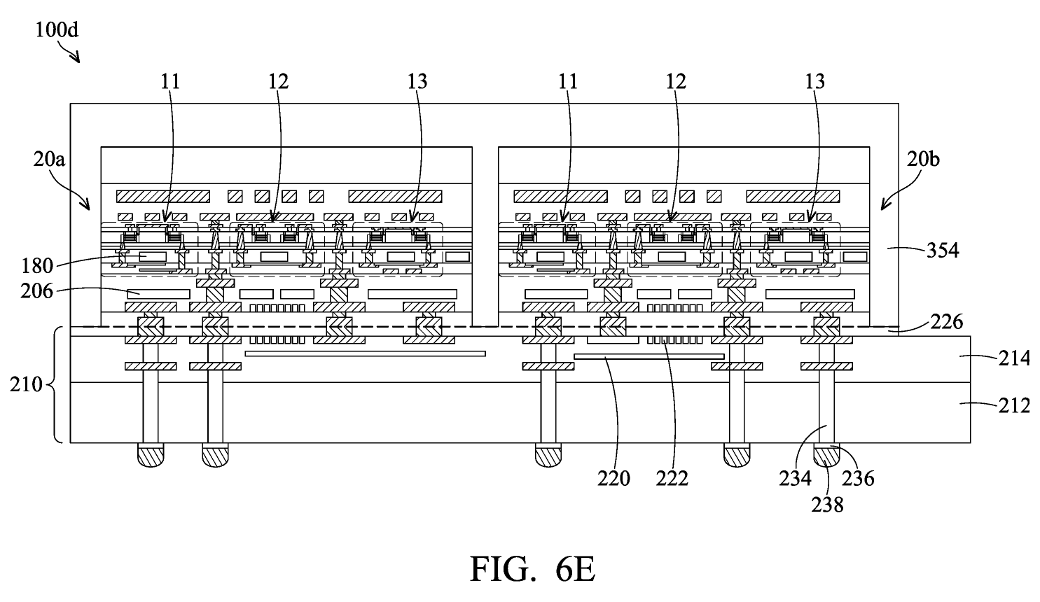

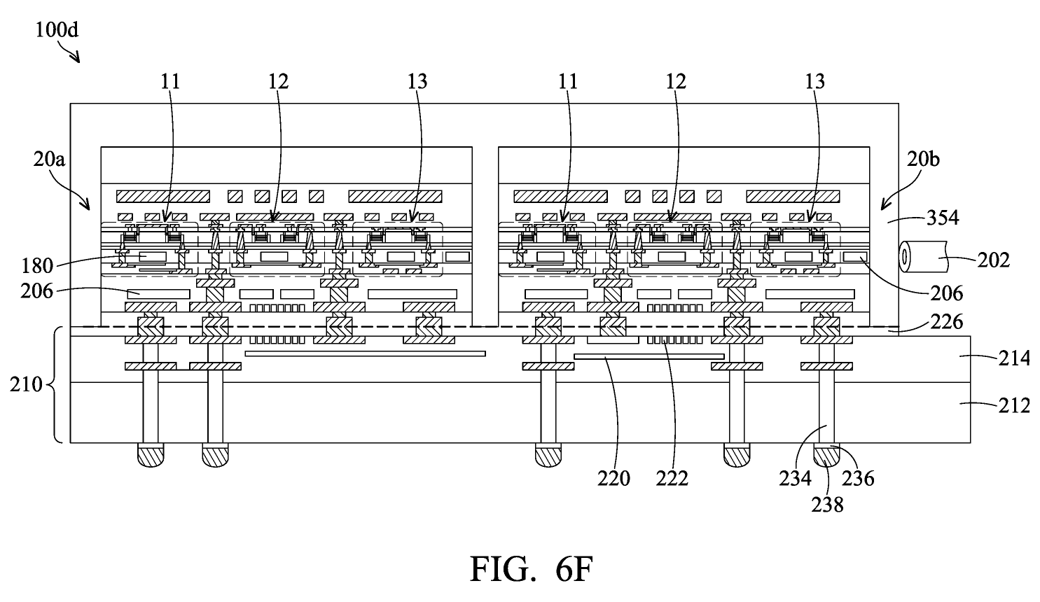

FIGS. 6A-6F show cross-sectional representations of various stages of forming a package structure 100d, in accordance with some embodiments of the disclosure. The package structure 100d is similar to, or the same as, the package structure 100a shown in FIG. 3G. Processes and materials used to form semiconductor device structure 100d may be similar to, or the same as, those used to form the semiconductor device structure 100a and a detailed description thereof is not repeated herein.

As shown in FIG. 6A, an optical interposer 210 is provided, the optical interposer 210 includes a substrate 212, and then a dielectric layer 214 formed over the substrate 212. Next, a bonding layer 226 is formed over the dielectric layer 214. Afterwards, TSV structures 234 are formed through the substrate 212 and the dielectric layer 214. The TSV structures 234 penetrate through the substrate 212 to provide a quick passage of power, data and ground through the substrate 212.

The optical interposer 210 can receive the various signals, either electrical signals or optical signals, translate the signals into optical signals if desired, route the optical signals as desired, translate the optical signals into electrical signals, and then send the electrical signals to the desired components.

The conductive layers 216 are formed in the dielectric layer 214, and third optical devices 220 are formed in the dielectric layer 214. The grating couplers 222 are formed in the dielectric layer 214. The grating couplers 222 are formed on the top surface of the dielectric layer 214.

The substrate 212 may be a semiconductor wafer such as a silicon wafer. Alternatively or additionally, the substrate 202 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the dielectric layer 214 includes low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the dielectric layers 214 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

In some embodiments, the conductive layers 216 include conductive materials, such as copper (Cu), copper alloy, aluminum (Al), aluminum alloys, combinations thereof or another applicable material. In some embodiments, the conductive layers 216 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

The third optical devices 220 may be optical waveguides (e.g., ridge waveguides, rib waveguides, buried channel waveguides, diffused waveguides, etc.), couplers (e.g., grating couplers, edge couplers, etc.), or the like. In some embodiments, the third optical devices 220 are a waveguide made of silicon nitride (SiN). In some embodiments, the material for the third optical devices 220 may be a translucent material. ). In some embodiments, the third optical devices 220 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

In some embodiments, the grating couplers 222 are utilized to receive signals from the third optical devices 220. In some embodiments, the grating couplers 222 may be used to receive and redirect incoming, off-plane signals from the optical fiber 202 (shown in FIG. 6F), the first optical device 180, and the second optical device 206 into the third optical devices 220.

A conductive pad 228 is formed in the bonding layer 226, and the conductive pad 228 is electrically connected to and in direct contact with the conductive layer 216. In some embodiments, the bonding layer 226 includes silicon oxide. In some other embodiments, the bonding layer 226 includes polymer material, such as benzocyclobutene (BCB) polymer, polyimide (PI), or polybenzoxazole (PBO) or another applicable material. The conductive pad 228 is formed on the top surface of the bonding layer 226. In some embodiments, the conductive pad 228 includes conductive materials, such as copper (Cu), copper alloy, aluminum (Al), aluminum alloy, or another applicable material. In some embodiments, the conductive pad 228 are formed by electroplating, chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

TSV trenches (not shown) are formed through the substrate 212 and the dielectric layer 214 to expose the conductive layer 216 from the back side surface of the substrate 212. Next, a liner (not shown) may be formed in the TSV trench, a diffusion barrier layer (not shown) is formed on the liner layer, and a conductive material is formed in the diffusion barrier layer. When the TSV trenches have been filled, the excess liner layer, diffusion barrier layer and the conductive material are removed by a planarization process such as chemical mechanical polishing (CMP) process.

In some embodiments, the liner layer is made of an insulating material, such as oxides, nitrides or another applicable material. In some embodiments, the diffusion barrier layer is tantalum (Ta), tantalum nitride (TaN), titanium (Ti), titanium nitride (TiN), cobalt tungsten (CoW) or another applicable material. In some embodiments, the conductive materials is made of copper (Cu), copper alloy, aluminum (Al), aluminum alloy, or another applicable material.

In some embodiments, the liner layer, the diffusion barrier layer and the conductive material are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

After the TSV structure 234 are formed, UBM layers 236 are formed below the TSV structure 234, and the conductive connectors 238 are formed below the UBM layers 236. The conductive connectors 238 are electrically connected to the conductive layers 216 by the TSV structure 234.

In some embodiments, the UBM layers 236 include titanium (Ti), titanium nitride (TiN), tantalum (Ta), tantalum nitride (TaN), tungsten (W), titanium tungsten (TiW), nickel (Ni), gold (Au), chrome (Cr), copper (Cu), copper alloy, another applicable material, or a combination thereof. In some embodiments, the conductive connectors 238 include copper (Cu ), a copper alloy, or another applicable material. In some embodiments, the UBM layers 236 and conductive connectors 238 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 6B, the dies 20a, 20b are prepared, in accordance with some embodiments of the disclosure. The dies 20a, 20b are prepared by the following steps. A bonding layer 326 is formed below the dielectric layer 196 of the interconnect structure 190 of the semiconductor structure 100c of FIG. 5, and then the structure 100c of FIG. 5 is diced into dies 20a, 20b. The conductive pads 328 are formed in the bonding layer 326.

The die 20a includes the semiconductor structures 10 and the first optical devices 180, the second optical devices 206 and the electro-optic effect material layer 186. The die 20b also includes the semiconductor structures 10 and the first optical devices 180, the second optical devices 206 and the electro-optic effect material layer 186. Each of the dies 20a, 20b includes the electrical devices and the optical devices are formed on opposite sidewall surfaces of the optical fiber 202.

The grating couplers 322 are formed in the dielectric layer 196 of the interconnect structure 190. In some embodiments, the grating couplers 322 are utilized to receive signals from the second optical devices 206. In some embodiments, the grating couplers 322 may be used to receive and redirect incoming, off-plane signals from the optical fiber 202 (shown in FIG. 6F) into the second optical devices 206.

The conductive pads 328 of the dies 20a, 20b face the conductive pads 228 of the optical interposer 210, and the bonding layer 326 of the dies 20a, 20b face the bonding layer 226 of the optical interposer 210. In addition, the grating couplers 222 face the grating couplers 322.

In some embodiments, the conductive pads 328 include conductive materials, such as copper (Cu), copper alloy, aluminum (Al), aluminum alloy, or another applicable material. In some embodiments, the conductive pads 328 are formed by electroplating, chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 6C, the die 20a and the die 20b are bonded to the optical interposer 210, in accordance with some embodiments of the disclosure.

Before the die 20a and the die 20b are bonded to the optical interposer 210, the dies 20a, 20b and the optical interposer 210 are aligned, such that conductive pads 328 on dies 20a, 20b can be bonded to the conductive pads 228 on the optical interposer 210, and the bonding layer 326 of the dies 20a, 20b can be bonded to the bonding layer 226 of the optical interposer 210. In some embodiments, the alignment of the dies 20a, 20b and the optical interposer 210 may be achieved by using an optical sensing method.

After the alignment is performed, the dies 20a, 20b and the optical interposer 210 are bonded together by a hybrid bonding process. The dies 20a, 20b and the optical interposer 210 are hybrid bonded together by the application of pressure and heat.

The hybrid bonding involves at least two types of bonding, including metal-to-metal bonding and non-metal-to-non-metal bonding. As shown in FIG. 6C, a bonding structure 350 is formed between the dies 20a, 20b and the optical interposer 210. The bonding structure 350 is a hybrid bonding structure which includes the conductive pads 228, 328 bonded by metal-to-metal bonding and bonding layers 226, 326 bonded by non-metal-to-non-metal bonding. The bonding structure 350 has a metallic bonding interface 350a between conductive pads 228 and 328 but may not have a clear non-metallic interface between bonding layers 226 and 326 due to the reflowing process. As a result, fusion of the dies 20a, 20b and the optical interposer 210 forms a hybrid bonded device. In some embodiments, the bonded dies are baked, annealed, pressed, or otherwise treated to strengthen or finalize the bond.

Additionally, while the above description a hybrid bonding process, this is intended to be illustrative and is not intended to be limiting. In some other embodiments, the dies 20a, 20b may be bonded to the optical interposer 210 by direct surface bonding, metal-to-metal bonding, or another bonding process. A direct surface bonding process creates an oxide-to-oxide bond or substrate-to-substrate bond through a cleaning and/or surface activation process followed by applying pressure, heat and/or other bonding process steps to the joined surfaces. In other embodiments, the first semiconductor device 201 and the optical interposer 100 are bonded by metal-to-metal bonding that is achieved by fusing conductive elements. Any suitable bonding process may be utilized, and all such methods are fully intended to be included within the scope of the embodiments.

Additionally, in some embodiments, the electrical bonding that is present between the dies 20a, 20b and the optical interposer 210 (e.g., the electrical connections between the conductive pads 228 and the conductive pads 328) are the paths that each signal (either optical or electrical) follows in order to communicate between the dies 20a, 20b and the optical interposer 210.

Next, as shown in FIG. 6D, a package layer 354 is formed over the dies 20a, 20b and the optical interposer 210, in accordance with some embodiments of the disclosure. In some embodiments, underfill layer (not shown) is formed before forming the package layer 354, and there is an interface between the underfill layer and the package layer 354. The package layer 354 surrounds and protects the dies 20a, 20b and the optical interposer 210.

The package layer 354 is made of a molding compound material. The molding compound material may include a polymer material, such as an epoxy-based resin with fillers dispersed therein. In some embodiments, a liquid molding compound material is applied over the dies 20a, 20b. A thermal process is then used to cure the liquid molding compound material and to transform it into the package layer 354.

Afterwards, as shown in FIG. 6E, a portion of the package layer 354 and a portion of the bonding layer 226 are removed to expose the top surface of the dielectric layer 214 the optical interposer 210, in accordance with some embodiments of the disclosure. As a result, a sidewall surface of the package layer 354 is not aligned with a sidewall surface of the dielectric layer 214 of the optical interposer 210. Furthermore, a portion of the top surface of the optical interposer 210 is not covered by the package layer 354.

Next, as shown in FIG. 6F, the optical fiber 202 is formed adjacent to the die 20b, in accordance with some embodiments of the disclosure. The optical fiber 202 is used as an input/output port to the optical signal of the second optical devices 206. By placing the optical fiber 202 adjacent to the second optical devices 206 of the dies 20b, the optical signals leaving the optical fiber 202 are directed through the second optical devices 206.

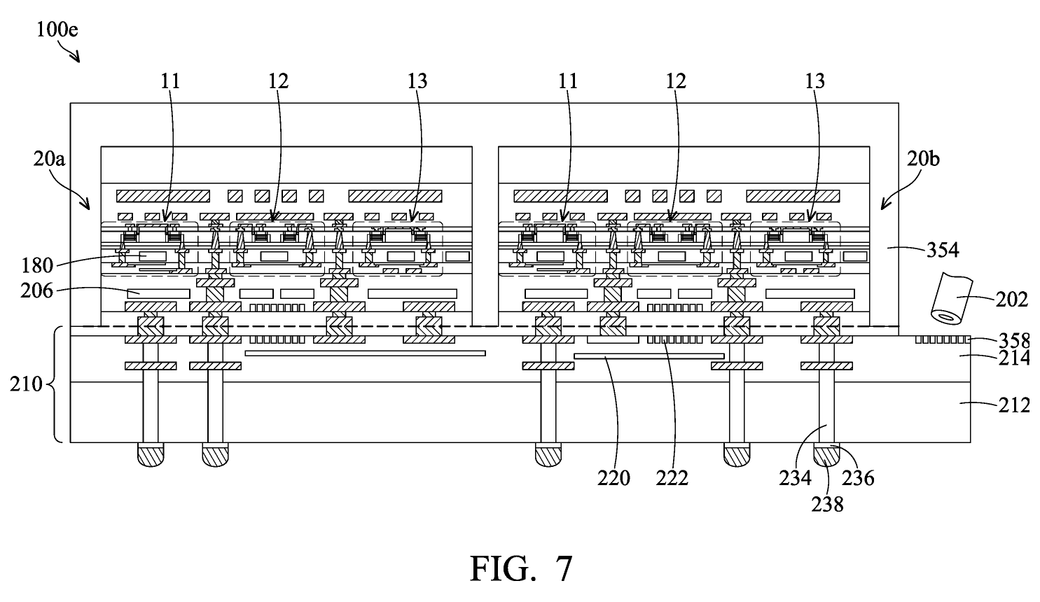

FIG. 7 shows a cross-sectional representation of a package structure 100e, in accordance with some embodiments of the disclosure. The package structure 100e is similar to, or the same as, the package structure 100d shown in FIG. 6F. Processes and materials used to form semiconductor device structure 100e may be similar to, or the same as, those used to form the semiconductor device structure 100d and a detailed description thereof is not repeated herein.

The difference between FIG. 7 and FIG. 6F is that a grating coupler 358 is formed in the dielectric layer 214 of the optical interposer 210. The optical fiber 202 is formed adjacent to and faces to the grating coupler 358. The optical fiber 202 is used as an input/output port to the optical signal of the grating coupler 358. By placing the optical fiber 202 adjacent to the grating coupler 358, the optical signals leaving the optical fiber 202 are directed through the grating coupler 358.

The grating coupler 358 may be used to receive and redirect incoming, off-plane signals from the optical fiber 202 (shown in FIG. 7) into the third optical devices 220.

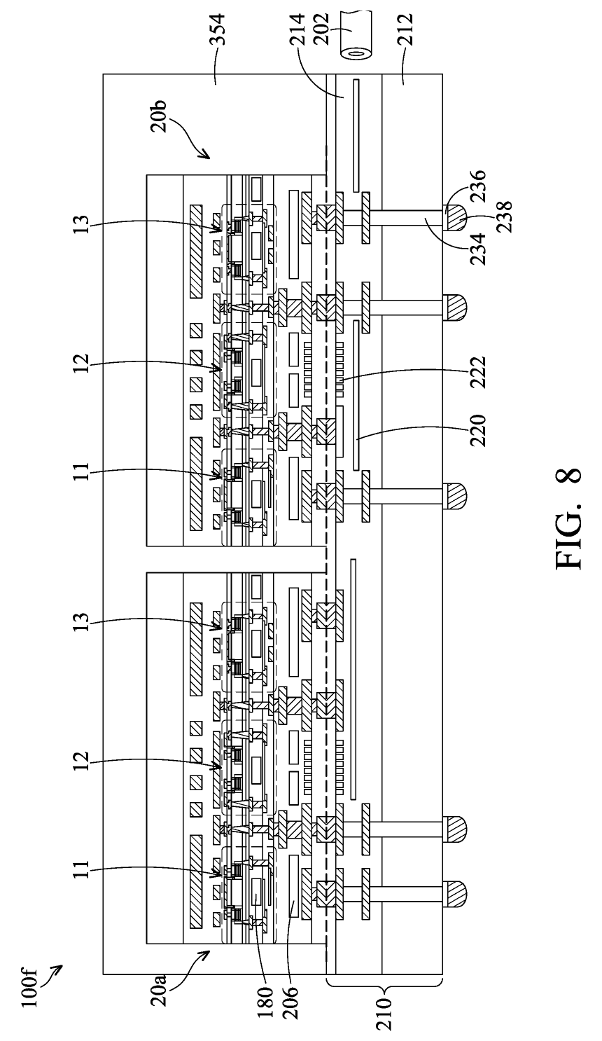

FIG. 8 shows a cross-sectional representation of a package structure 100f, in accordance with some embodiments of the disclosure. The package structure 100f is similar to, or the same as, the package structure 100d shown in FIG. 6F. Processes and materials used to form semiconductor device structure 100f may be similar to, or the same as, those used to form the semiconductor device structure 100d and a detailed description thereof is not repeated herein.

The difference between FIG. 8 and FIG. 6F is that the optical fiber 202 is adjacent to the third optical devices 220 of the optical interposer 210. The optical fiber 202 is used as an input/output port to the optical signal of the third optical devices 220. By placing the optical fiber 202 adjacent to the third optical devices 220, the optical signals leaving the optical fiber 202 are directed through the third optical devices 220.

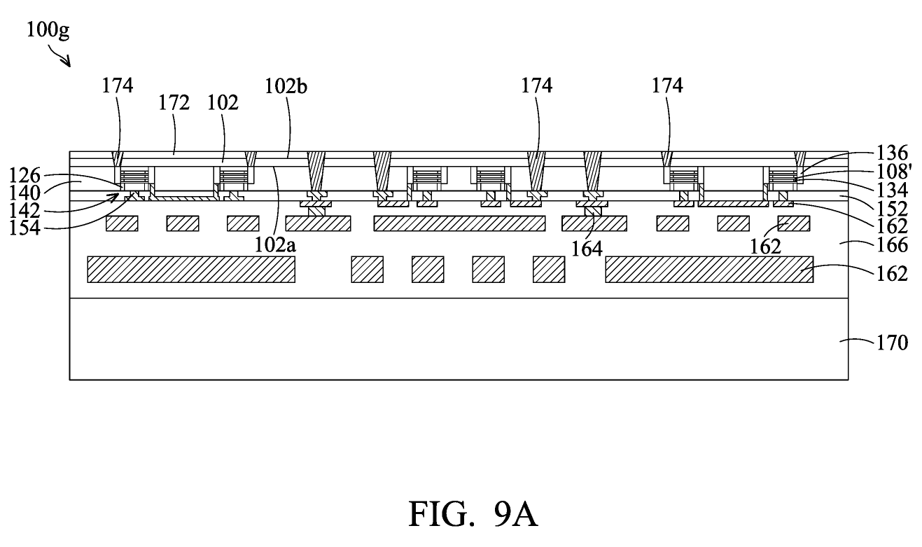

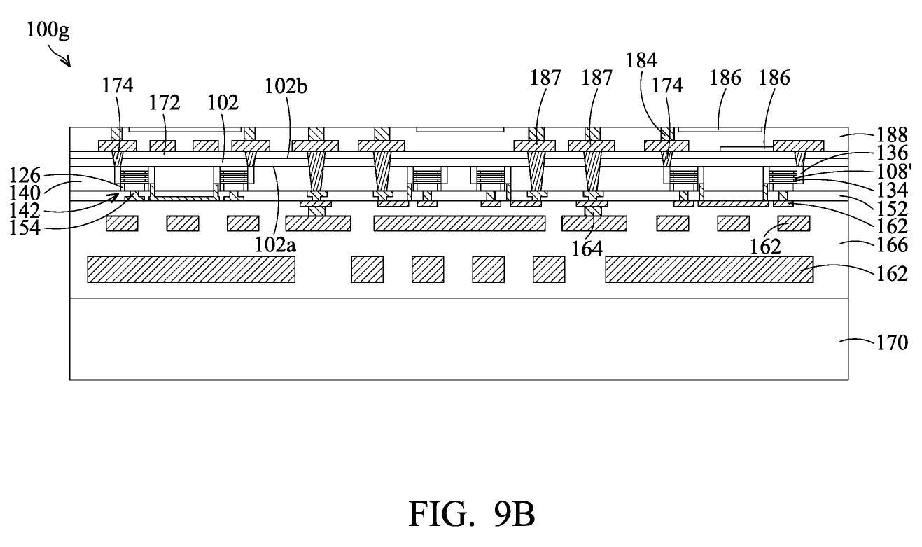

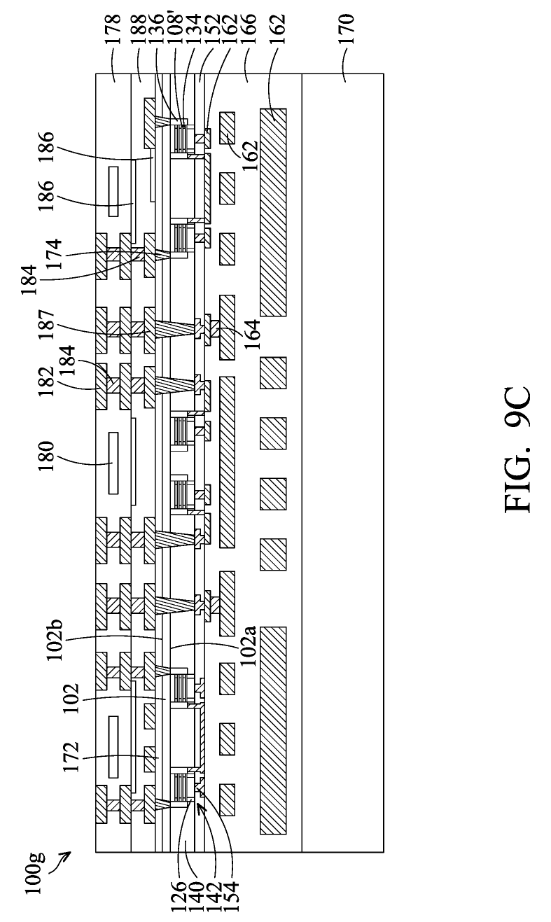

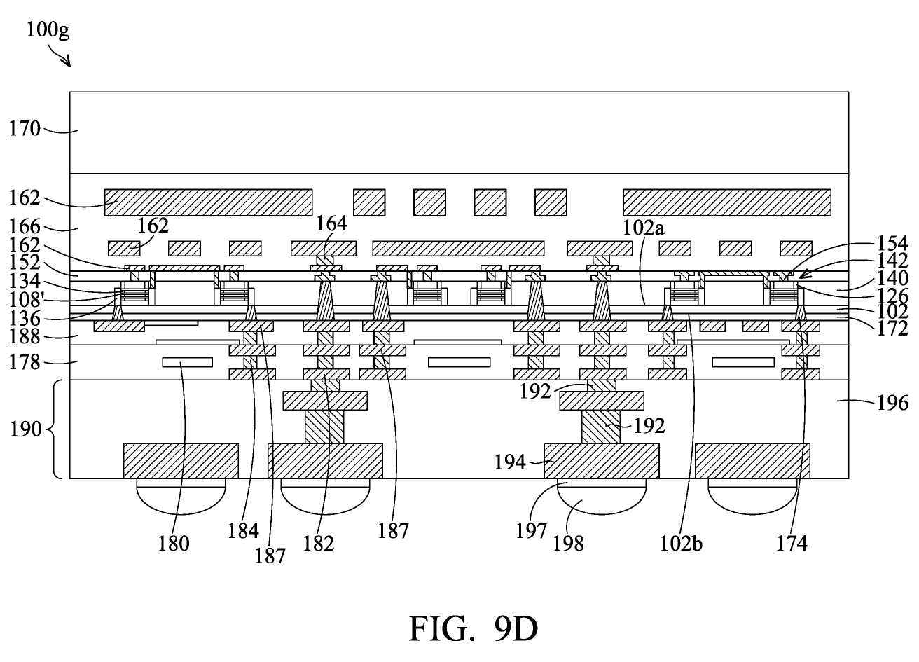

FIGS. 9A-9D show cross-sectional representations of various stages of forming a package structure 100g, in accordance with some embodiments of the disclosure. The package structure 100d is similar to, or the same as, the package structure 100a shown in FIG. 3G. Processes and materials used to form semiconductor device structure 100g may be similar to, or the same as, those used to form the semiconductor device structure 100a and a detailed description thereof is not repeated herein. The difference between FIG. 9D and FIG. 3G is that the formation of the electro-optic effect material layer 186 and the protective layer 188 is before the formation of the first optical devices 180.

As shown in FIG. 9A, the dielectric layer 172 is formed over the back-side surface 102b of the substrate 102, and then through-substrate via (TSV) structures 174 are formed through the dielectric layer 172 and the substrate 102, in accordance with some embodiments of the disclosure.

Afterwards, as shown in FIG. 9B, the electro-optic effect material layer 186, the conductive layer 187 and the protective layer 188 are formed over the dielectric layer 178, in accordance with some embodiments of the disclosure. The electro-optic effect material layer 186 and the conductive layer 187 are embedded in the protective layer 188. The electro-optic effect material layer 186 is in direct contact with the conductive layer 187 for transfer electrical signal. The protective layer 188 is used to protect the electro-optic effect material layer 186.

In some embodiments, the electro-optic effect material layer 186 includes graphene. In some embodiments, the electro-optic effect material layer 186 is a 2D material. The electro-optic effect material layer 186 may be one layer or multiple layers according to actual application. In some embodiments, the electro-optic effect material layer 186 is attached to or bonding to the dielectric layer 178. . In some embodiments, the electro-optic effect material layer 186 is made of graphene, and the graphene has a thickness in about 0.35 nm.

Next, as shown in FIG. 9C, the dielectric layer 178 is formed over the protective layer 188, and the first optical devices 180, the conductive layers 182, and the conductive plug 184 are formed in the dielectric layer 178, in accordance with some embodiments of the disclosure.

In some embodiments, the dielectric layer 178 includes low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

The first optical devices 180 may be optical waveguides (e.g., ridge waveguides, rib waveguides, buried channel waveguides, diffused waveguides, etc.), couplers (e.g., grating couplers, edge couplers, etc.), or the like. In some embodiments, the first optical devices 180 are a waveguide made of silicon nitride (SiN). In some embodiments, the material for the first optical devices 180 may be a translucent material. In some embodiments, the first optical devices 180 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 9D, the interconnect structure 190 is formed over the dielectric layer 178, in accordance with some embodiments of the disclosure. The interconnect structure 190 is a back-side interconnect structure. The interconnect structure 160 may be used as a redistribution (RDL) structure for routing. Next, the structure of FIG. 9C is flipped.

The interconnect structure 190 includes the contact plugs 192, the conductive layers 194, the dielectric layers 196 and the UBM layers 197 and the conductive connectors 198. The contact plugs 192 and the conductive layers 194 are embedded in the dielectric layer 196.

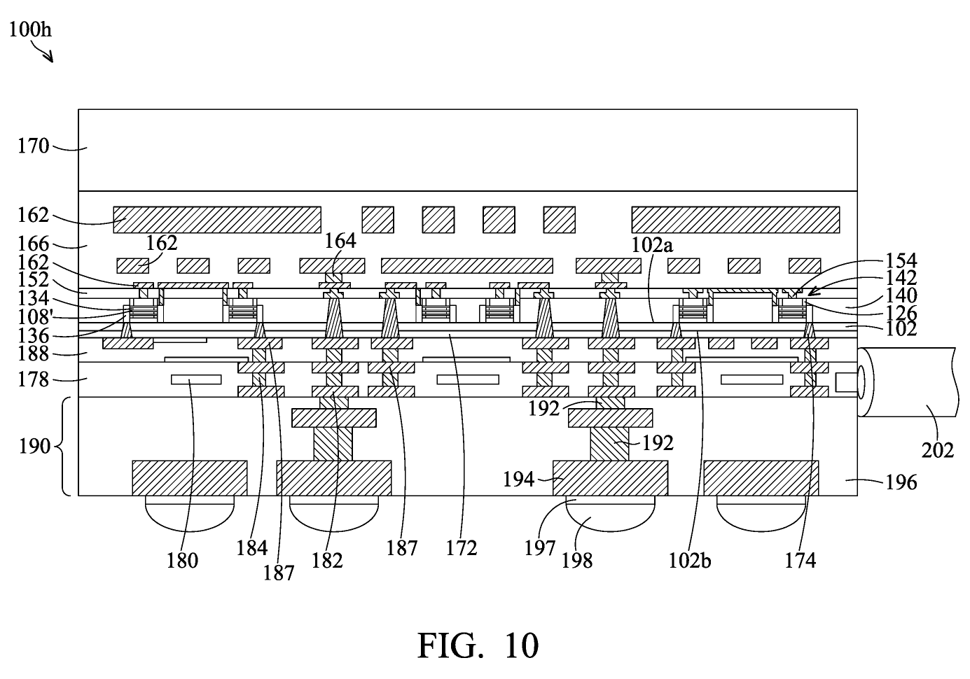

FIG. 10 shows a cross-sectional representation of a package structure 100h, in accordance with some embodiments of the disclosure. The package structure 100h is similar to, or the same as, the package structure 100g shown in FIG. 9D. Processes and materials used to form semiconductor device structure 100h may be similar to, or the same as, those used to form the semiconductor device structure 100g and a detailed description thereof is not repeated herein.

The difference between FIG. 10 and FIG. 9D is that an additional optical fiber 202 is formed adjacent to the first optical devices 180. The optical fiber 202 is used as an input/output port to the optical signal of the first optical devices 180. By placing the optical fiber 202 adjacent to the first optical devices 180, the optical signals leaving the optical fiber 202 are directed through the first optical devices 180.

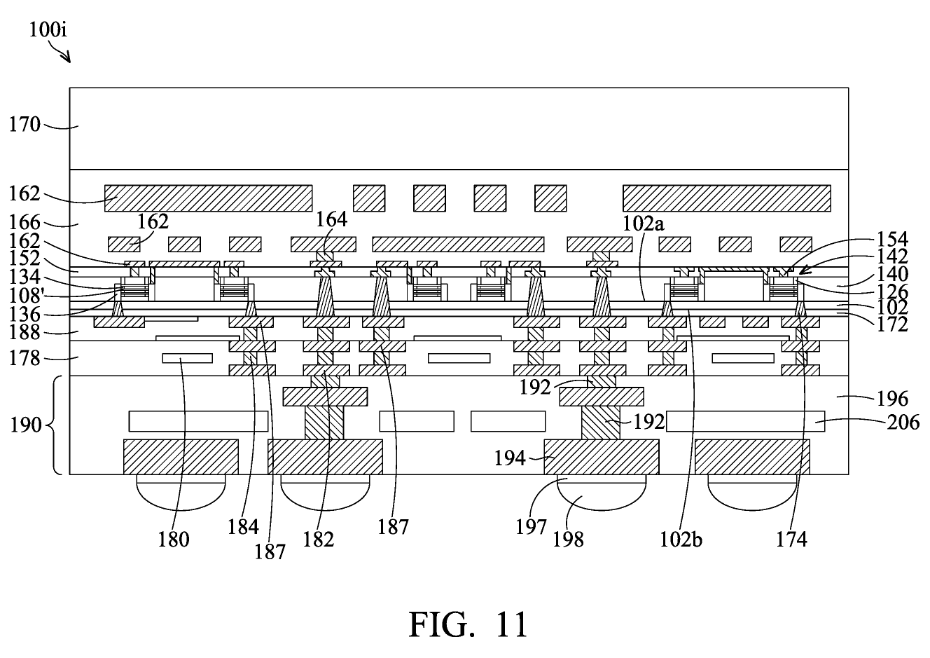

FIG. 11 shows a cross-sectional representation of a package structure 100i, in accordance with some embodiments of the disclosure. The package structure 100i is similar to, or the same as, the first package structure 100g shown in FIG. 9D. Processes and materials used to form semiconductor device structure 100i may be similar to, or the same as, those used to form the semiconductor device structure 100g and a detailed description thereof is not repeated herein.

The difference between FIG. 11 and FIG. 9D is the second optical devices 206 are formed in the back-side interconnect structure 190. The second optical devices 206 and the first optical devices 180 cooperate to transfer the optical signal more efficiency.

The second optical devices 206 may be optical waveguides (e.g., ridge waveguides, rib waveguides, buried channel waveguides, diffused waveguides, etc.), couplers (e.g., grating couplers, edge couplers, etc.), or the like. In some embodiments, the second optical devices 206 are a waveguide made of silicon nitride (SiN). In some embodiments, the material for the second optical devices 206 may be a translucent material. ). In some embodiments, the second optical devices 206 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

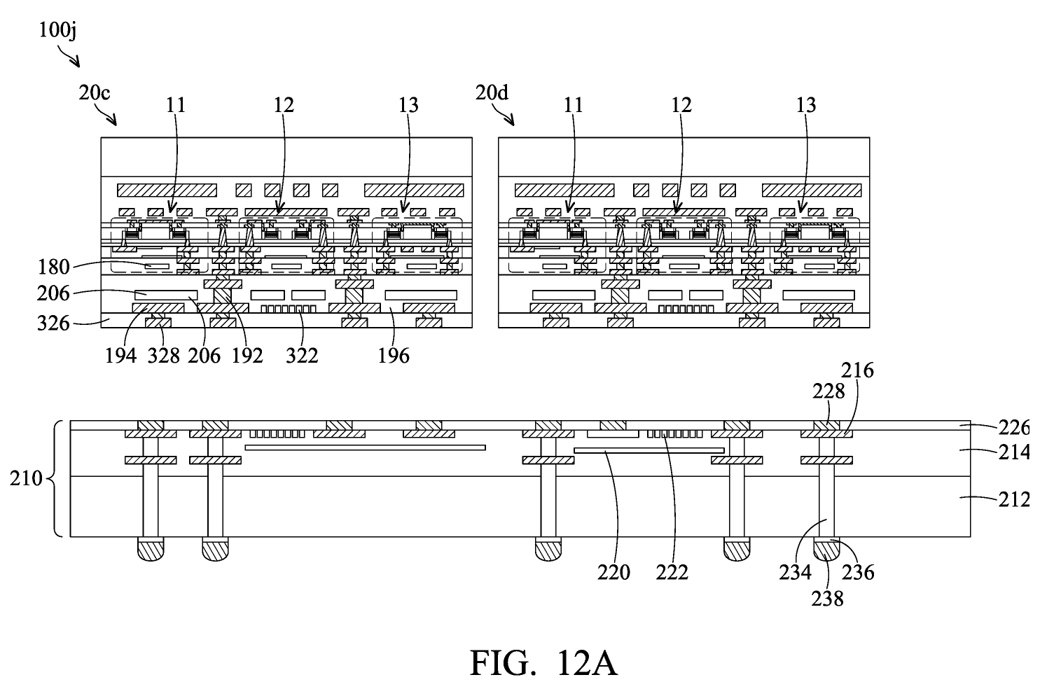

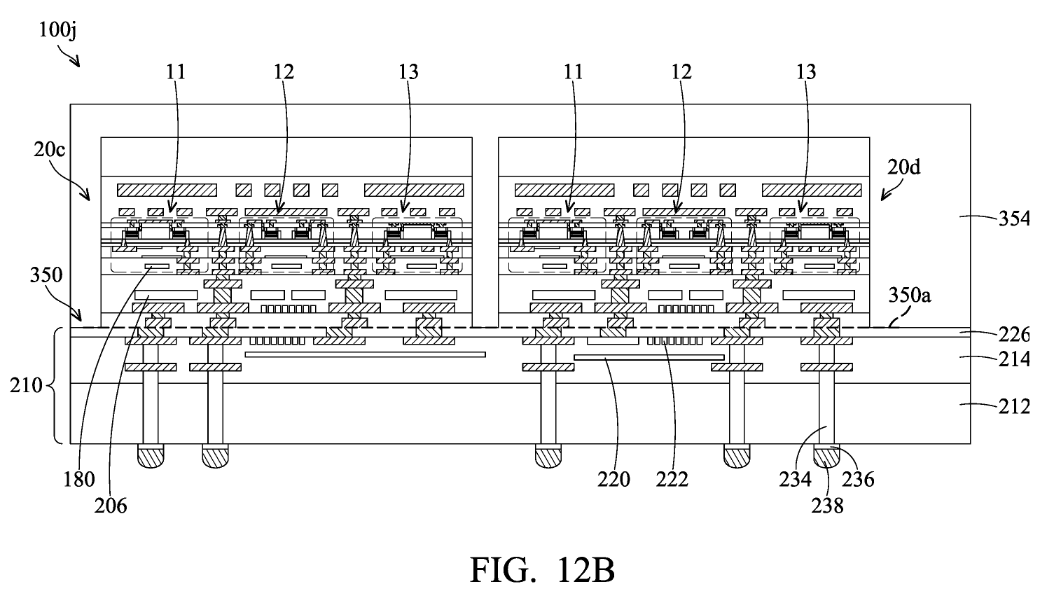

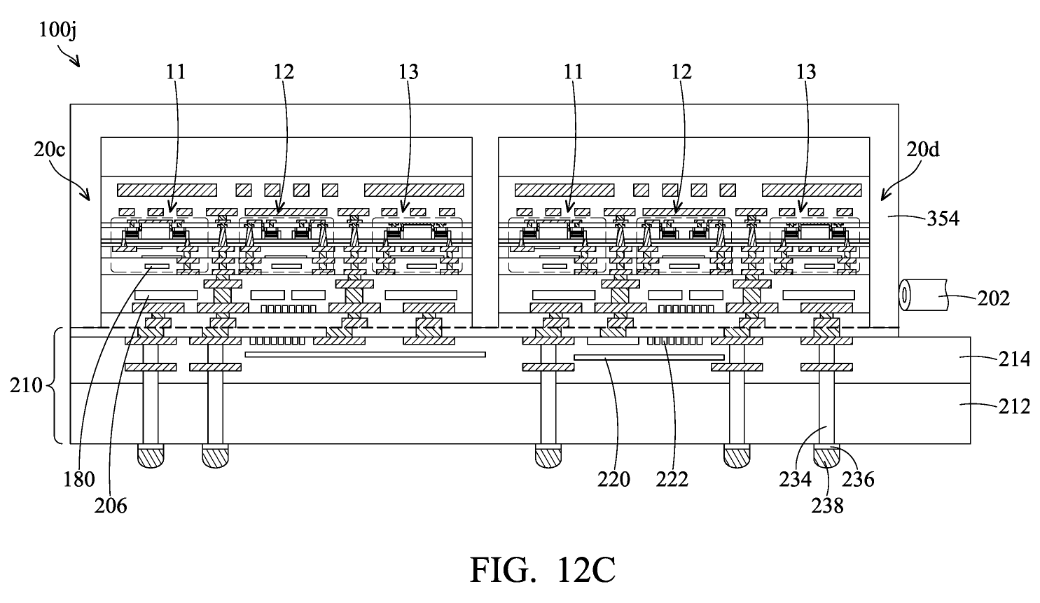

FIGS. 12A-12C show cross-sectional representations of various stages of forming a package structure 100j, in accordance with some embodiments of the disclosure. The package structure 100j is similar to, or the same as, the package structure 100a shown in FIG. 3G. Processes and materials used to form semiconductor device structure 100j may be similar to, or the same as, those used to form the semiconductor device structure 100a and a detailed description thereof is not repeated herein.

As shown in FIG. 12A, the optical interposer 210 is provided, and the dies 20c, 20d from the semiconductor structure 100g of FIG. 9D are prepared, in accordance with some embodiments of the disclosure. The dies 20c, 20d are prepared by the following steps. The bonding layer 326 is formed below the dielectric layer 196 of the interconnect structure 190 of the semiconductor structure 100g of FIG. 9D, and then the structure of FIG. 9D is diced into dies 20c, 20d. The conductive pads 328 are formed in the bonding layer 326. The grating coupler 322 is formed in the dielectric layer 196.

The optical interposer 210 includes the substrate 212 and the dielectric layer 214 formed over the substrate 212. The bonding layer 226 is formed over the dielectric layer 214, and the conductive pads 228 are formed in the bonding layer 226. Afterwards, TSV structures 234 are formed through the substrate 212 and the dielectric layer 214. The TSV structures 234 penetrate through the substrate 212 to provide a quick passage of power, data and ground through the substrate 212. The conductive layers 216 are formed in the dielectric layer 214, and the third optical devices 220 are formed in the dielectric layer 214. The grating couplers 222 are formed in the dielectric layer 214. The conductive pads 328 of the dies 20c, 20d face the conductive pads 328 of the optical interposer 210, and prepare to perform the bonding process. In addition, the grating couplers 222 face the grating couplers 322.

Afterwards, as shown in FIG. 12B, the die 20c, 20d are bonded to the optical interposer 210, in accordance with some embodiments of the disclosure.

Before the dies 20c, 20d are bonded to the optical interposer 210, the dies 20c, 20d and the optical interposer 210 are aligned, such that conductive pads 328 on dies 20c, 20d can be bonded to the conductive pads 228 on the optical interposer 210, and the bonding layer 326 of the dies 20c, 20d can be bonded to the bonding layer 226 of the optical interposer 210. In some embodiments, the alignment of the dies 20c, 20d and the optical interposer 210 may be achieved by using an optical sensing method. All of the conductive pads 228 and 328 may align, some of the conductive pads 228 and 328 may offset, or all of the conductive pads 228 and 328 may offset. In some embodiments, the conductive pads 328 on dies 20c, 20d and the conductive pads 228 on the optical interposer 210 are aligned. In some embodiments, some of the conductive pads 328 on dies 20c, 20d and the conductive pads 228 on the optical interposer 210 are aligned.

After the alignment is performed, the dies 20c, 20d and the optical interposer 210 are bonded together by hybrid bonding process. The dies 20c, 20d and the optical interposer 210 are hybrid bonded together by the application of pressure and heat.

The hybrid bonding involves at least two types of bonding, including metal-to-metal bonding and non-metal-to-non-metal bonding. As shown in FIG. 12B, the hybrid bonding structure 350 is formed between the dies 20c, 20d and the optical interposer 210. The hybrid bonding structure 350 includes the conductive pads 228, 328 bonded by metal-to-metal bonding and bonding layers 226, 326 bonded by non-metal-to-non-metal bonding. The bonding structure 350 has a metallic bonding interface 350a between conductive pads 228 and 328 but may not have a clear non-metallic interface between bonding layers 226 and 326 due to the reflowing process. As a result, fusion of the dies 20c, 20d and the optical interposer 210 forms a hybrid bonded device. In some embodiments, the bonded dies are baked, annealed, pressed, or otherwise treated to strengthen or finalize the bond.

After the hybrid bonding process, the package layer 354 is formed over the dies 20c, 20d and the optical interposer 210, in accordance with some embodiments of the disclosure. In some embodiments, underfill layer (not shown) is formed before forming the package layer 354, and there is an interface between the underfill layer and the package layer 354. The package layer 354 surrounds and protects the dies 20c, 20d and the optical interposer 210.

The package layer 354 is made of a molding compound material. The molding compound material may include a polymer material, such as an epoxy-based resin with fillers dispersed therein. In some embodiments, a liquid molding compound material is applied over the dies 20c, 20d. A thermal process is then used to cure the liquid molding compound material and to transform it into the package layer 354.

Next, as shown in FIG. 12C, a portion of the package layer 354 and a portion of the bonding layer 226 are removed to expose the top surface of the dielectric layer 214, in accordance with some embodiments of the disclosure. As a result, a sidewall surface of the package layer 354 is not aligned with a sidewall surface of the dielectric layer 214 of the optical interposer 210.

Next, the optical fiber 202 is formed adjacent to the die 20d, in accordance with some embodiments of the disclosure. The optical fiber 202 is used as an input/output port to the optical signal of the second optical devices 206. By placing the optical fiber 202 adjacent to the second optical devices 206, the optical signals leaving the optical fiber 202 are directed through the second optical devices 206.

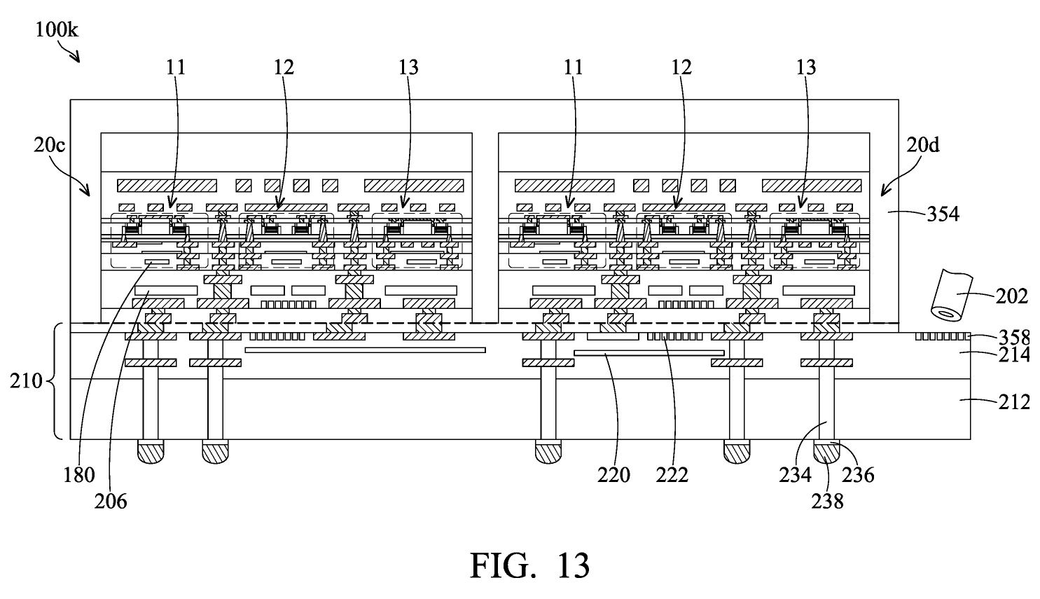

FIG. 13 shows a cross-sectional representation of a package structure 100k, in accordance with some embodiments of the disclosure. The package structure 100k is similar to, or the same as, the package structure 100j shown in FIG. 12C. Processes and materials used to form semiconductor device structure 100k may be similar to, or the same as, those used to form the semiconductor device structure 100j and a detailed description thereof is not repeated herein.

The difference between FIG. 13 and FIG. 12C is that the grating coupler 358 is formed in the dielectric layer 214 of the optical interposer 210. The optical fiber 202 is formed adjacent to and faces to the grating coupler 358. The optical fiber 202 is used as an input/output port to the optical signal of the grating coupler 358. By placing the optical fiber 202 adjacent to the grating coupler 358, the optical signals leaving the optical fiber 202 are directed through the grating coupler 358.

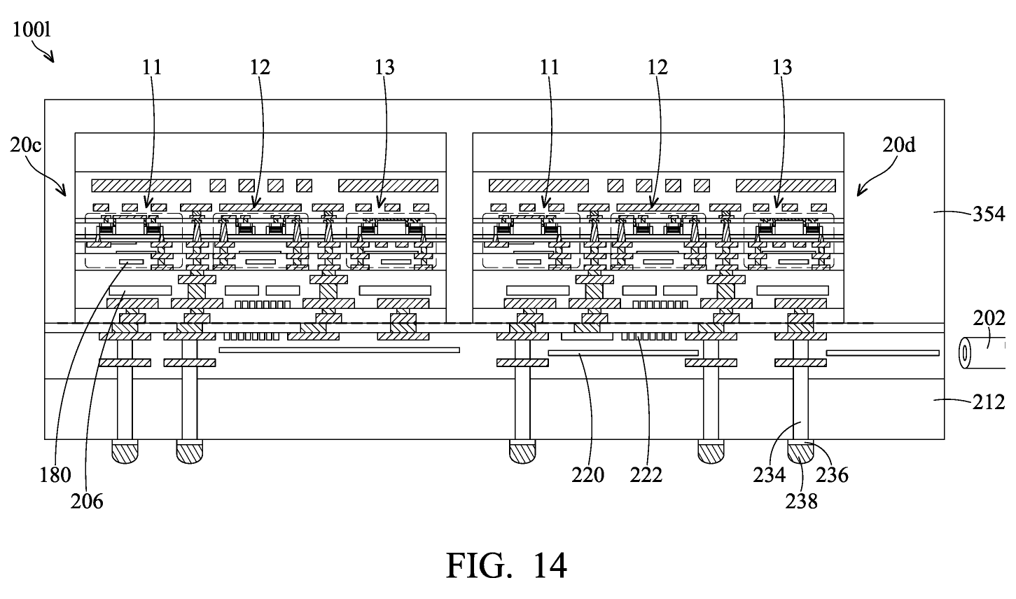

FIG. 14 shows a cross-sectional representation of a package structure 100l, in accordance with some embodiments of the disclosure. The package structure 100l is similar to, or the same as, the package structure 100j shown in FIG. 12C. Processes and materials used to form semiconductor device structure 100l may be similar to, or the same as, those used to form the semiconductor device structure 100j and a detailed description thereof is not repeated herein.

The difference between FIG. 14 and FIG. 12C is that the optical fiber 202 is adjacent to the third optical devices 220 of the optical interposer 210. The optical fiber 202 is used as an input/output port to the optical signal of the third optical devices 220. By placing the optical fiber 202 adjacent to the third optical devices 220, the optical signals leaving the optical fiber 202 are directed through the third optical devices 220.

Embodiments for forming a package structure and method for formation the same are provided. A semiconductor structure (or electrical device) is formed on a front-side surface of the substrate, and a first optical devices and an electro-optic effect material layer are formed on a back-side surface of the substrate. The substrate can be a wafer, and the electrical device (e.g. the semiconductor device) and the optical device (e.g. the first optical device and the electro-optic effect material layer) are integrated into one wafer. Note that bonding layer is absent between the electrical device (e.g. the semiconductor device) and the optical device (e.g. the first optical devices and the electro-optic effect material layer). Since the electrical device and the optical device are formed on single wafer or chip without a bonding layer, rather on different chips, the passage of the electrical signals and the optical signals are reduced and the transmission speed of the electrical signals and the optical signals are improved.

In some embodiments, a package structure is provided. The package structure includes a substrate having a front-side surface and a back-side surface, and an electrical device formed over the front-side surface of a substrate. The package structure includes a dielectric layer formed below and in direct contact with the back-side of the substrate, and a first optical device formed in the dielectric layer. The package structure also includes a protective layer formed below or above the first optical device; and an electro-optic effect material layer formed in the protective layer.

In some embodiments, a package structure is provided. The package structure includes an optical interposer and a first die formed over the optical interposer. The first die includes an electrical device, a first optical device formed below the electrical device, and a graphene layer formed above or below the first optical device.

In some embodiments, a method for forming a package structure is provided. The method includes forming an electrical device over a front-side surface of a substrate, and forming a first optical device over a back-side surface of the substrate. The method includes forming an electro-optic effect material layer over the optical device, and forming a protective layer on the electro-optic effect material layer.

In some embodiments, a package structure is provided. The package structure includes an optical interposer and a first die. The optical interposer comprises a first optical device. The first die is formed over the optical interposer. The first die comprises an electrical device, wherein the electrical device comprises a gate structure, an S/D structure and a conductive plug below the S/D structure. The first die includes a second optical device formed below the electrical device, and an electro-optic effect material layer formed above or below the second optical device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate having a front-side surface and a back-side surface;
an electrical device formed over the front-side surface of the substrate;
a first optical device formed on the back-side surface of the substrate;
a protective layer formed below or above the first optical device; and
an electro-optic effect material layer formed in the protective layer.

2. The package structure as claimed in claim 1, further comprising:
a dielectric layer formed below and in direct contact with the back-side surface of the substrate; and
an optical fiber formed adjacent to the first optical device.

3. The package structure as claimed in claim 1, further comprising:
a second optical device formed below the first optical device.

4. The package structure as claimed in claim 1, further comprising:
a through-substrate via (TSV) structure connected to the electrical device and the electro-optic effect material layer.

5. The package structure as claimed in claim 4, wherein the electrical device comprises:
nanostructures formed over the substrate; and
an S/D structure connected to the nanostructures, wherein the TSV structure is connected to the S/D structure.

6. The package structure as claimed in claim 1, wherein the first optical device comprises an optical waveguide or a coupler.

7. The package structure as claimed in claim 1, further comprising:
a front-side interconnect structure formed over the electrical device; and
a back-side interconnect structure formed below the protective layer.

8. The package structure as claimed in claim 1, wherein the electrical device and the first optical device are formed in one die.

9. The package structure as claimed in claim 1, wherein the electro-optic effect material layer comprises a graphene layer.

10. A package structure, comprising:
an optical interposer; and
a first die formed over the optical interposer, wherein the first die comprises:
an electrical device;
a first optical device formed below the electrical device; and
a graphene layer formed above or below the first optical device.

11. The package structure as claimed in claim 10, further comprising:
a bonding structure between the optical interposer and the first die, wherein the bonding structure comprises a first bonding layer bonded to a second bonding layer, and a first conductive pad bonded to a second conductive pad.

12. The package structure as claimed in claim 10, further comprising:
a first grating coupler formed in the first die; and
a second grating coupler formed in the optical interposer.

13. The package structure as claimed in claim 10, further comprising:
an optical fiber formed adjacent to the optical device, or adjacent to a top surface of the optical interposer.

14. The package structure as claimed in claim 10, further comprising:
a second optical device formed below the graphene layer.

15. The package structure as claimed in claim 10, further comprising:
a second die formed over the optical interposer, wherein the second die is adjacent to the first die, and the second die comprises another graphene layer.

16. The package structure as claimed in claim 15, further comprising:
a package layer surrounding the first die and the second die, wherein a portion of a top surface of the optical interposer is not covered by the package layer.

17. A package structure, comprising:
an optical interposer, wherein the optical interposer comprises a first optical device; and
a first die formed over the optical interposer, wherein the first die comprises:
an electrical device, wherein the electrical device comprises a gate structure, an S/D structure and a conductive plug below the S/D structure;
a second optical device formed below the electrical device; and
an electro-optic effect material layer formed above or below the second optical device.

18. The package structure as claimed in claim 17, wherein the first die further comprises a grating coupler below the second optical device.

19. The package structure as claimed in claim 17, wherein the optical interposer further comprises a grating coupler at a top surface of the optical interposer.

20. The package structure as claimed in claim 17, further comprising:
a package layer surrounding the first die, wherein a portion of a top surface of the optical interposer is not covered by the package layer.
